(19) United States
(12) Patent Application Publication
(10) Pub. No.: US 2017/0347479 A1
(43) Pub. Date: Nov. 30, 2017

(54) UNIT ATTACHMENT APPARATUS AND ELECTRONIC DEVICE SYSTEM

(71) Applicant: Mitsubishi Electric Corporation, Tokyo (JP)

(72) Inventor: Takashi ANDO, Tokyo (JP)

(73) Assignee: Mitsubishi Electric Corporation, Tokyo (JP)

(21) Appl. No.: 15/535,449

(22) PCT Filed: Dec. 19, 2014
(86) PCT No.: PCT/JP2014/083757

§ 371 Date: Jun. 13, 2017

(51) Int. Cl. H05K 7/14; H05K 5/03; H05K 1/18; H05K 9/00; H05K 7/20; H01R 12/71

(52) U.S. Cl. CPC H05K 7/1417; H05K 9/0022; H05K 7/20436; H05K 7/1427; H05K 5/03; H05K 1/181; H01R 12/716

(57) ABSTRACT

The present invention includes a plate member having a same sectional shape along a first direction, an opening provided at a part of the plate member, a motherboard installed on the plate member and forming a housing space between the plate member and a second principal surface of the motherboard, and a thermal-conductive electromagnetic-wave absorbing sheet installed on a rear surface of a power semiconductor device that is an electronic component mounted on the second principal surface of the motherboard from the side of the opening. The motherboard has a first principal surface including a unit mount portion on which an electronic device unit is to be mounted, and the second principal surface parallel to the first principal surface, and is installed on the plate member.

### FIELD

The present invention relates to a unit attachment apparatus and an electronic device system, on which a plurality of electronic device units each having a substrate held in a housing can be installed.

### BACKGROUND

Electronic device systems in which electronic device units are attached to unit attachment apparatuses each of which including a motherboard, and a housing that protects the motherboard and electronic components installed on the motherboard have been used. Among these electronic device systems, in a system that uses an industrial control device such as a sequencer, many electronic device units are installed on a base unit that serves as a motherboard to constitute an electronic device system.

For example, as described in Patent Literature 1, an electronic device apparatus such as a mobile phone transmitter/receiver is used in a state where a plurality of transmitting units, a power-supply circuit unit, and an electronic circuit module are attached to side plates thereof. In such an electronic device system, a heat releasing property of a control device constituted of the electronic circuit module is demanded as well as stability of a structure for attaching the electronic device units to a unit attachment apparatus.

### CITATION LIST

### Patent Literature

Patent Literature 1: Japanese Patent Application Laid-open No. H11-204971

### SUMMARY

### Technical Problem

However, in the technique described in Patent Literature 1 described above, the apparatus configuration is complicated and large. When the configuration is intended to be downscaled, there is a problem that the heat releasing property is particularly insufficient and the electromagnetic property is also insufficient.

Furthermore, in a case of a configuration in which many electronic components are mounted on both front and back surfaces of a motherboard, thinning of a housing space formed on a rear side of the motherboard is an important issue in addition to the electromagnetic property of the electronic components and the heat releasing measures.

The present invention has been achieved in view of the above problems, and an object of the present invention is to provide a unit attachment apparatus that is thin and has good noise characteristics and heat releasing performance.

### Solution to Problem

To solve the above problems and achieve an object, there is provided a unit attachment apparatus according to the present invention including: a plate member that has a same sectional shape along a first direction; an opening that is provided at a part of the plate member; a motherboard that has a first principal surface including a unit mount portion on which an electronic device unit is to be mounted and a second principal surface parallel to the first principal surface, that is installed on the plate member, and that forms a housing space between the second principal surface and the plate member; and a thermal-conductive electromagnetic-wave absorbing sheet that is installed on a rear surface of an electronic component, which is mounted on the second principal surface of the motherboard, from a side of the opening.

### Advantageous Effects of Invention

According to the present invention, a unit attachment apparatus that is thin and has good noise characteristics and heat releasing performance can be obtained.

### BRIEF DESCRIPTION OF DRAWINGS

FIG. 1 is a perspective view of a unit attachment apparatus according to a first embodiment of the present invention, as viewed from a rear surface side.

FIG. 2 is a perspective view of the unit attachment apparatus according to the first embodiment of the present invention, in a state where a lid is removed therefrom, as viewed from the rear surface side.

FIG. 3 is a view illustrating the unit attachment apparatus according to the first embodiment of the present invention, being a sectional view taken along a line A-A in FIG. 1.

FIG. 4 is a relevant-part enlarged view illustrating the periphery of an opening of the unit attachment apparatus according to the first embodiment of the present invention.

FIG. 5 is a relevant-part enlarged sectional view of the unit attachment apparatus according to the first embodiment of the present invention.

FIG. 6 is a perspective view illustrating a step of attaching a lid to the unit attachment apparatus according to the first embodiment of the present invention, as viewed from the rear surface side.

FIG. 7 is a view illustrating a step of attaching a lid to the unit attachment apparatus according to the first embodiment of the present invention, being a sectional view taken along a line A-A in FIG. 6.

FIG. 8 is a perspective view of the unit attachment apparatus, as viewed from a front surface side thereof.

FIG. 9 is a sectional view of the unit attachment apparatus according to the first embodiment of the present invention, illustrating a state of being attached to a wall surface.

FIG. 10 is a perspective view of the unit attachment apparatus according to the first embodiment of the present invention, illustrating a state where an electronic device unit is attached thereto.

FIG. 11 is a sectional view of a unit attachment apparatus according to a second embodiment of the present invention, illustrating a state of being attached to a wall surface.

FIG. 12 is a sectional view of a unit attachment apparatus according to a third embodiment of the present invention, illustrating a state of being attached to a wall surface.

### DESCRIPTION OF EMBODIMENTS

Exemplary embodiments of a unit attachment apparatus and an electronic device system according to the present invention will be explained below in detail base on the drawings. The present invention is not limited by the embodiments, and appropriate modifications can be made within a range not departing from the scope of the invention. In the drawings explained below, scale sizes of respective layers and members may be illustrated differently from actual sizes in some cases to facilitate understanding, and this similarly applies to relationships between the drawings. Further, for better understanding of the drawings, hatchings are applied in planar views in some cases.

### First Embodiment

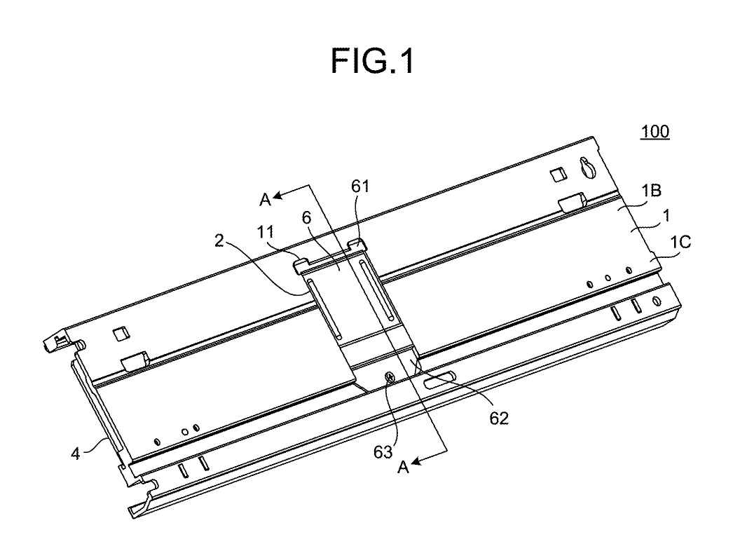

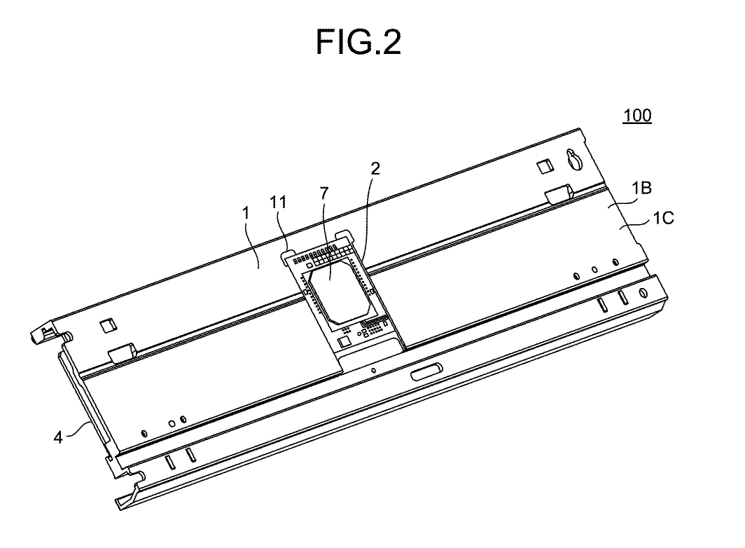

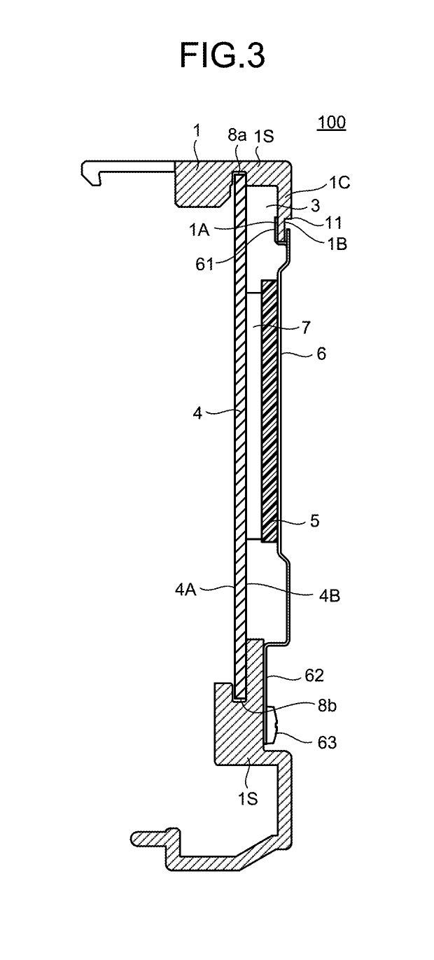

FIG. 1 is a perspective view of a unit attachment apparatus according to a first embodiment of the present invention, as viewed from a rear surface side. FIG. 2 is a perspective view of the unit attachment apparatus in a state where a lid is removed therefrom, as viewed from the rear surface side. FIG. 3 is a sectional view taken along a line A-A in FIG. 1.

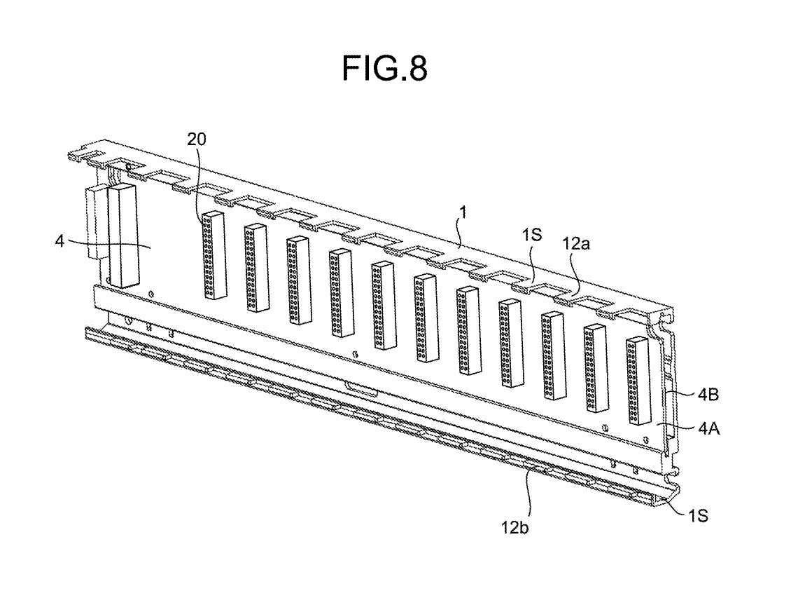

A unit attachment apparatus 100 according to the present embodiment is characterized in including a plate member 1 having a same sectional shape in a first direction, an opening 2 provided at a part of the plate member 1, and a motherboard 4 installed on the plate member 1 and forming a housing space 3 between the motherboard 4 and a rear surface portion 1C of the plate member 1. The motherboard 4 has a first principal surface 4A including unit mount portions, and a second principal surface 4B parallel to the first principal surface 4A. The plate member 1 is an aluminum plate formed by extrusion molding. Connectors 20 are formed on the unit mount portions and an electronic device unit 300 can be inserted to and removed from each connector 20, which will be described later with reference to FIG. 8. The first direction is a longitudinal direction.

The plate member 1 has the rear surface portion 1C, and side surface portions 1S that are provided on two sides of the rear surface portion 1C in the longitudinal direction, respectively. The plate member 1 has groove portions 8a and 8b U-shaped in cross section on the side surface portions 1S, for installing two sides of the motherboard 4 thereon, respectively. The groove portions 8a and 8b position the plate member 1. Opposed long sides of the motherboard 4 are engaged with and fixed to the groove portions 8a and 8b, respectively, whereby the motherboard 4 is fixed to the plate member 1 and the housing space 3 is formed between the plate member 1 and the motherboard 4. That is, a narrow housing space 3 is formed between a first principal surface 1A located on an inner side of the rear surface portion 1C of the plate member 1 and the motherboard 4, and a second principal surface 1B located on an outer side of the rear surface portion 1C abuts on a wall surface to which the unit attachment apparatus 100 is attached.

The opening 2 is formed at the rear surface portion 1C of the plate member 1 and a stainless-steel lid 6 is attached thereto to close the opening 2. A power semiconductor device 7 that constitutes a programmable logic controller (PLC) is installed as an electronic component to the motherboard 4 on the side of a rear surface of the motherboard 4, the rear surface being the second principal surface 4B. The power semiconductor device 7 that constitutes the PLC is an electronic component having a high heat generating property. The power semiconductor device 7 is a resin-seal control IC (semiconductor integrated circuit) component and abuts on the lid 6 via a thermal-conductive electromagnetic-wave absorbing sheet 5 interposed therebetween.

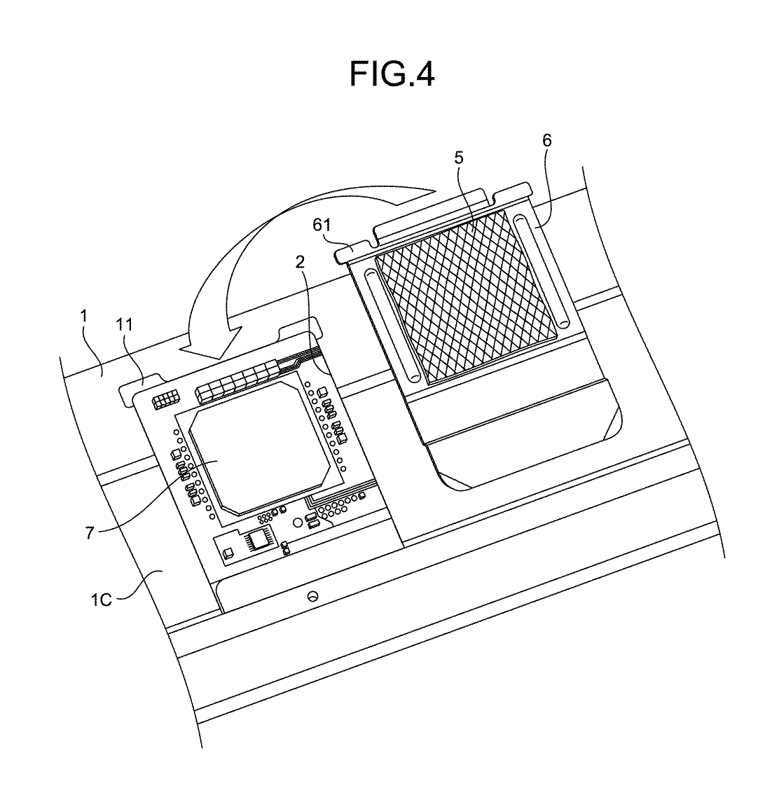

The lid 6 is constituted of an iron sheet. As illustrated in FIG. 4, the lid 6 can be attached to or detached from the rear surface portion 1C of the plate member 1 and has an engaging function to be capable of being engaged to cover the opening 2.

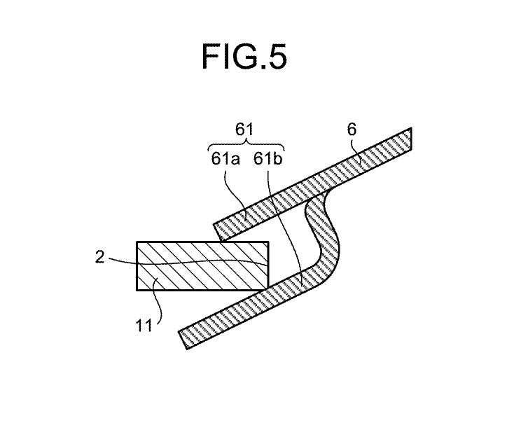

As illustrated in a relevant-part enlarged sectional view of FIG. 5, the lid 6 is formed by punching an iron sheet being about 0.5 to 5 millimeters thick. The lid 6 has protruding portions 61 each including a first protruding piece 61a and a second protruding piece 61b and being U-shaped in cross section. Meanwhile, the plate member 1 has stepped portions 11 at two adjacent corners on the peripheral edge of the opening 2. By placing each of the stepped portions 11 between the first protruding piece 61a and the second protruding piece 61b, the protruding portions 61 of the lid 6 and the stepped portions 11 can be fitted with each other, and the lid 6 is fitted with the plate member 1 and is fixed thereto in a state of closing the opening 2 of the plate member 1. The first protruding pieces 61a and the second protruding pieces 61b can be positioned in a direction along long sides of the plate member 1 by the stepped portions 11 provided at the two adjacent corners on the peripheral edge of the opening 2. FIG. 5 is a relevant-part enlarged sectional view illustrating a state of the protruding portion 61 of the lid 6 and the stepped portion 11 on the peripheral edge of the opening 2 before being fitted with each other.

The thermal-conductive electromagnetic-wave absorbing sheet 5 is fixed to a surface of the lid 6 that faces the first principal surface 1A of the plate member 1. The thermal-conductive electromagnetic-wave absorbing sheet 5 is obtained, for example, by a method of forming a metal vapor-deposited layer on a surface of a thermal conductive sheet that is obtained by mixing and dispersing thermal conductive powder in a resin having flexibility and elasticity. Alternatively, the thermal-conductive electromagnetic-wave absorbing sheet 5 is obtained by a method of thermocompressively bonding an electromagnetic-wave absorbing sheet, which is obtained by mixing and dispersing flat metal powder in a resin having flexibility and elasticity, and a thermal conductive sheet to each other. Because a resin package of the power semiconductor device 7 is made of an epoxy resin, the thermal-conductive electromagnetic-wave absorbing sheet 5 is easily fixed thereto by only being pressed due to the adhesive property. Because being easily detached by application of force, the thermal-conductive electromagnetic-wave absorbing sheet 5 is easy to handle.

A resin such as a silicon resin, an epoxy resin, an olefin resin, or a fluorine resin is used as the resin having flexibility and elasticity. When a resin having a high thermal conductivity is used, the thermal-conductive electromagnetic-wave absorbing sheet 5 having higher elastic modulus can be obtained.

Aluminum hydroxide, magnesium hydroxide, calcium carbonate, magnesium carbonate, calcium oxide, magnesium oxide, alumina powder, aluminum nitride, boron nitride, silicon carbide, crystalline silica, or non-crystalline silica can be applied as the thermal conductive powder.

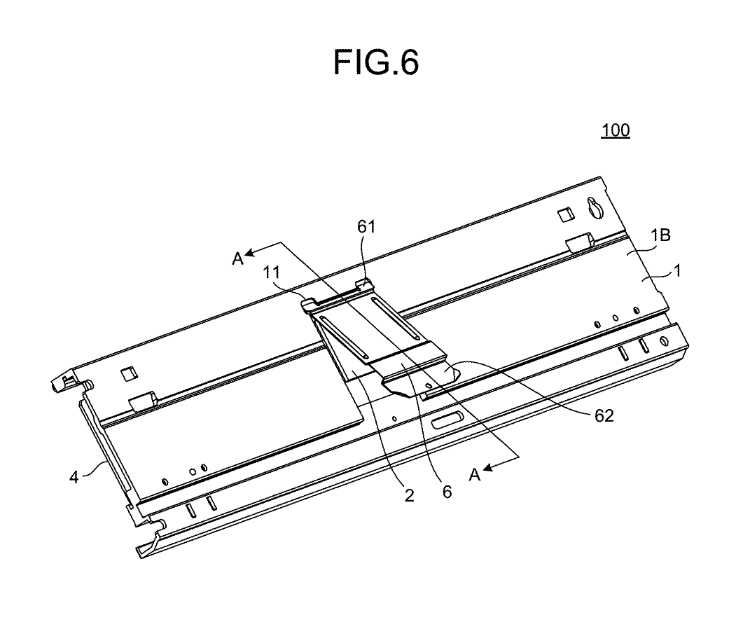

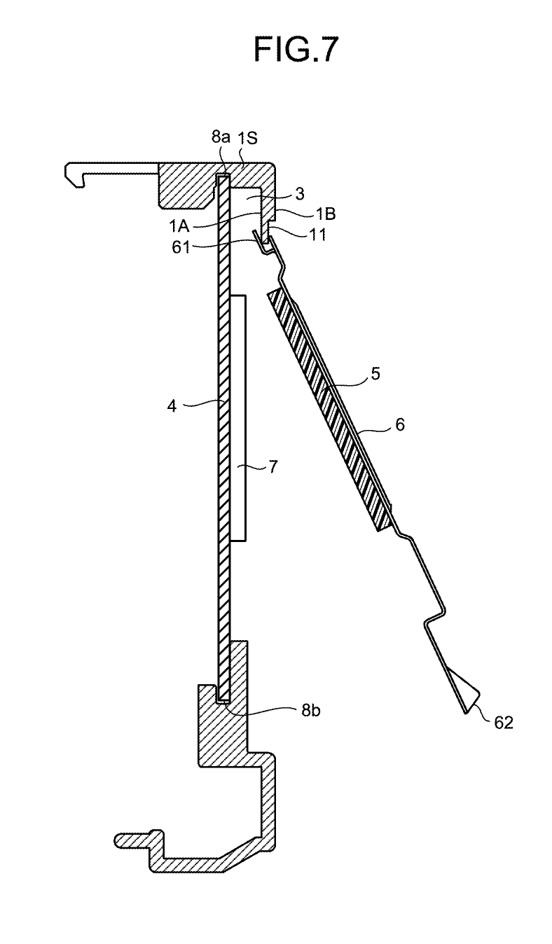

An assembling method of the unit attachment apparatus according to the first embodiment is described next. FIGS. 6 and 7 are a perspective view and a sectional view illustrating a step of attaching the lid 6 to the opening 2 of the plate member 1, respectively. FIG. 8 is a perspective view of the unit attachment apparatus as viewed from a front surface side of the unit attachment apparatus.

First, a plate member 1 is molded by extrusion molding of a metallic material having aluminum as a major component, and an elongated plate member 1 including the rear surface portion 1C and the two side surface portions 1S formed to extend toward the motherboard 4 along two long sides of the rear surface portion 1C is formed. Subsequently, the molded plate member 1 is cut to a predetermined length and is divided. On each of the divided plate-like bodies 1, the opening 2 and the stepped portions 11 on the peripheral edge of the opening 2 are formed by punching. Formation of the opening 2 can be performed at the same time of the extrusion molding by inserting a mold for forming the stepped portion 11 intermittently.

An epoxy resin substrate having circuit patterns formed on the first and second principal surfaces 4A and 4B, respectively, is used as the motherboard 4. As illustrated in FIG. 8, the connectors 20 are mounted on the circuit pattern of the first principal surface 4A of the motherboard 4 having the circuit patterns formed thereon. On the other hand, the power semiconductor device 7 is mounted on the second principal surface 4B on the rear surface side.

Next, the motherboard 4 is slidingly inserted into the groove portions 8a and 8b that are U-shaped in cross section and are provided on the side surface portions 1S on the two sides of the plate member 1 in the longitudinal direction in such a manner that two sides of the motherboard 4 engage therewith, respectively, and is fixed. Because being a thin metallic plate, the plate member 1 has elasticity and can elastically fix the motherboard 4 that is slidingly inserted thereto.

Subsequently, as illustrated in FIGS. 6 and 7, the lid 6 having the thermal-conductive electromagnetic-wave absorbing sheet 5 bonded thereon is attached to the rear surface side being the side of the second principal surface 1B of the plate member 1. The stepped portions 11 at the two adjacent corners on the peripheral edge of the opening 2 of the plate member 1 are engaged between the first protruding pieces 61a and the second protruding pieces 61b constituting the protruding portions 61, respectively, which are U-shaped in cross section and are provided at the two adjacent corners of the peripheral edge of the lid 6. The lid 6 is then caused to pivot toward the plate member 1 on a line segment passing through end edges of the two stepped portions 11 of the opening 2 as an axis, a fixing piece 62 of the lid 6 is positioned along remaining two corners of the peripheral edge of the opening 2, and the lid 6 is fixed to the plate member 1 with a screw 63 as illustrated in FIG. 3.

In this way, the unit attachment apparatus 100 illustrated in FIG. 1 is completed. FIG. 8 is a perspective view of the motherboard 4 as viewed from the side of the first principal surface 4A.

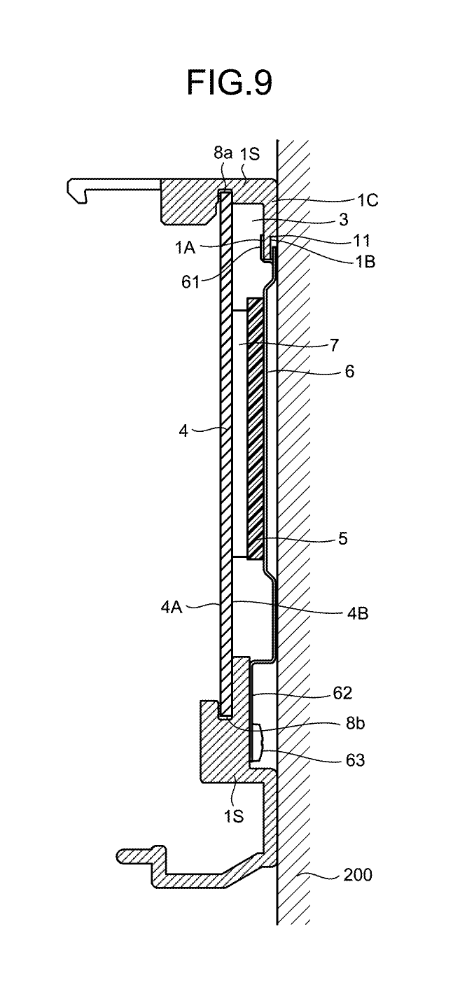

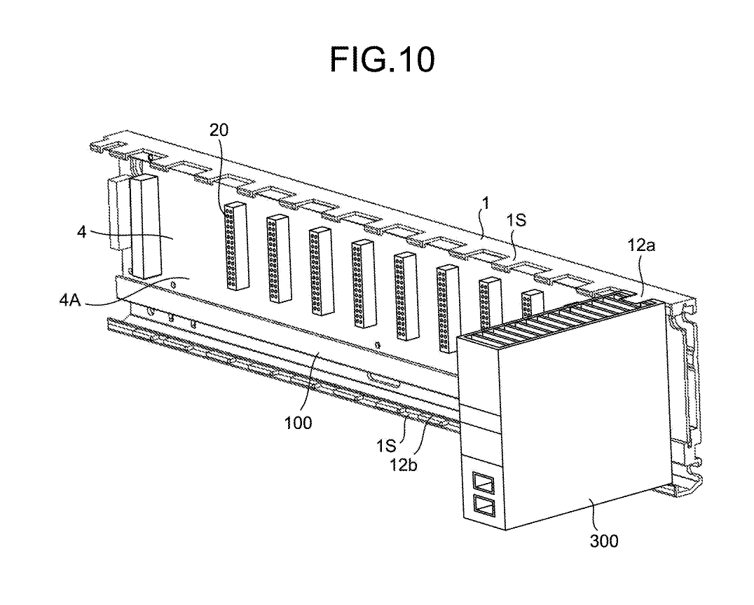

As illustrated in FIG. 9, the unit attachment apparatus 100 formed in this manner is attached to a wall surface 200 with an attachment hook (not illustrated). The electronic device unit 300 is connector-jointed to the connector 20 provided on the first principal surface 4A of the motherboard 4 as illustrated in FIG. 10, whereby an electronic device system is completed. First and second support pieces 12a and 12b are provided on the side surface portions 1S of the plate member 1 of the unit attachment apparatus 100 to support two surfaces of the electronic device unit 300, respectively.

In the electronic device system obtained as described above, the unit attachment apparatus 100 can be thinned and heat of the power semiconductor device 7 provided on the rear surface of the motherboard 4 can be efficiently released to the lid 6 via the thermal-conductive electromagnetic-wave absorbing sheet 5. The heat is then efficiently released from the lid 6 to the wall surface 200. That is, the electronic device system has a structure in which heat of the power semiconductor device 7 is not released to inside the housing space 3 but the lid 6 provided on the opening 2 is caused to abut on the wall surface 200 outside the unit attachment apparatus 100 to release heat. Therefore, the heat of the power semiconductor device 7 is not released to inside the housing through heat radiation but can be efficiently released to the external wall surface 200 through heat conduction via the thermal-conductive electromagnetic-wave absorbing sheet 5. Accordingly, thinning can be realized, and compressive bonding of the thermal-conductive electromagnetic-wave absorbing sheet 5 further improves the thermal conductivity and the electromagnetic-wave suppressing effect.

The plate member 1 constituting the housing space 3 is formed by a manufacturing method of performing extrusion molding using a metallic material and thereafter forming a detailed shape. Therefore, even when the number of units to be attached varies, the same mold can be used, so that the versatility is high and the cost can be lowered. Furthermore, at the time of assembly, after the motherboard 4 is aligned with the groove portion 8a on the upper side and the groove portion 8b on the lower side in FIG. 3 and then is slidingly inserted thereto, the motherboard 4 and the plate member 1 are fixed to each other. The lid 6 having the thermal-conductive electromagnetic-wave absorbing sheet 5 bonded thereto is thereafter attached to be aligned with the opening 2 and the stepped portions 11, and the plate member 1 and the lid 6 are fixed to each other. At this time, positioning is performed with the first protruding piece 61a and the second protruding piece 61b, so that the assembly can be achieved without the motherboard 4 and the lid 6 being in contact with each other, a thin housing space can be formed, and the assembly operability is satisfactory.

The number and the shape of the opening, the engagement structure of the opening with the lid, the numbers of the thermal-conductive electromagnetic-wave absorbing sheet and the electronic components are not limited to those in the embodiment described above and can be appropriately changed.

The structure of the plate member can also be appropriately changed. In the present embodiment, the protruding portions 61 are provided at two adjacent corners in the first direction along the long sides of the plate member 1. However, the positions or the number of the protruding portions 61 is not particularly limited, and one protruding portion or three or more protruding portions can be provided.

### Second Embodiment

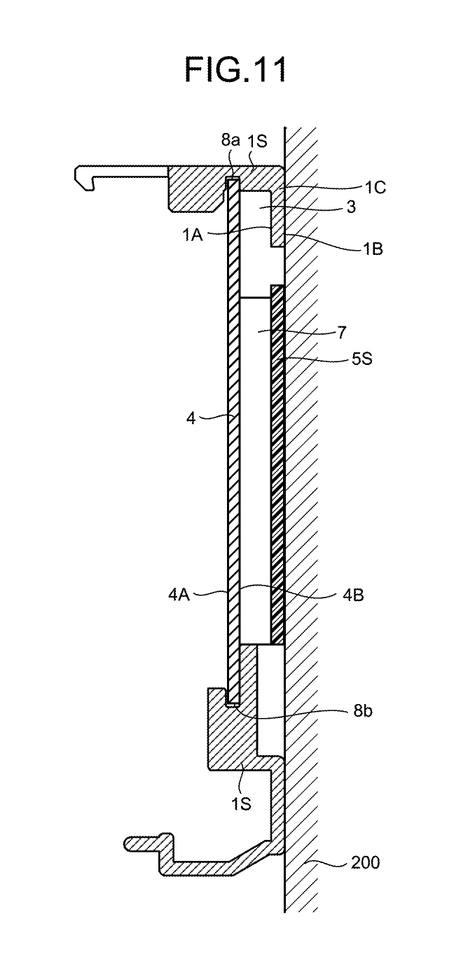

FIG. 11 is a sectional view of an electronic device system according to a second embodiment of the present invention.

A difference of the electronic device system according to the present embodiment from that according to the first embodiment is that the lid 6 is not provided. Instead of using the lid 6, the electronic device system according to the present embodiment has a configuration in which a thermal-conductive electromagnetic-wave absorbing sheet 5S is placed between the power semiconductor device 7 and the wall surface 200 on which the unit attachment apparatus 100 is installed, and the electromagnetic-wave absorbing sheet 5S is brought into direct contact with the wall surface 200 on which the unit attachment apparatus 100 is installed. In the present embodiment, a case where the power semiconductor device 7 is thicker than that in the first embodiment is illustrated. In this case, the present embodiment can also be achieved by adjusting the thickness of the electromagnetic-wave absorbing sheet 5S according to the height of the power semiconductor device 7. Other configurations are identical to those of the first embodiment, and thus explanations thereof will be omitted.

Also this configuration provides effective heat releasing property and electromagnetic-wave absorbing property. Because the thermal-conductive electromagnetic-wave absorbing sheet 5S can be tightly fixed to the resin package of the power semiconductor device 7 without requiring any particular adhesive, the assembly is also fairly satisfactory.

Furthermore, only by adjusting the electromagnetic-wave absorbing sheet 5S, the electromagnetic-wave absorbing sheet 5S can be efficiently mounted regardless of the height of the power semiconductor device 7 to be installed. Therefore, the versatility is also high.

The thermal-conductive electromagnetic-wave absorbing sheet 5S has an identical composition to that of the thermal-conductive electromagnetic-wave absorbing sheet 5 used in the first embodiment. Accordingly, it suffices to appropriately cut the thermal-conductive electromagnetic-wave absorbing sheet 5 to be adapted to the power semiconductor device 7. The thermal-conductive electromagnetic-wave absorbing sheets 5 can be stacked to form a two-layer structure or a three-layer structure.

### Third Embodiment

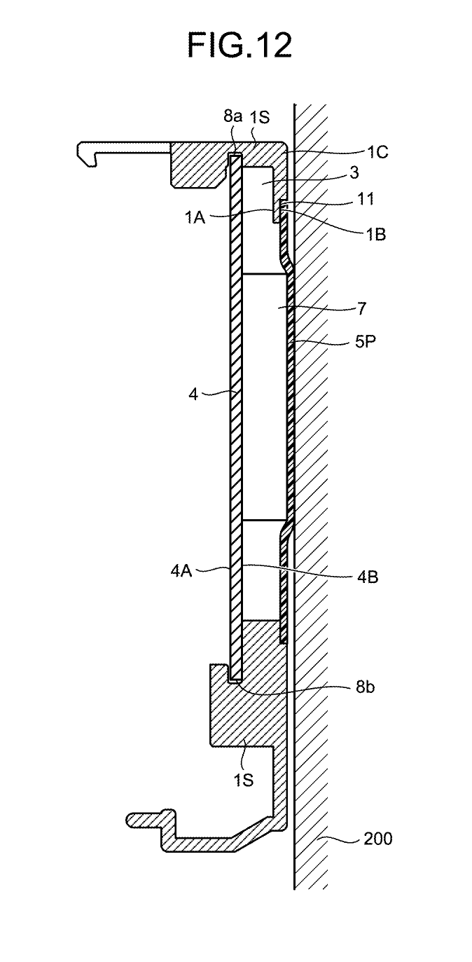

FIG. 12 is a sectional view of an electronic device system according to a third embodiment of the present invention.

Also in the present embodiment, a difference from the electronic device system according to the first embodiment is that the lid 6 is not provided. Instead of using the lid 6, the present embodiment has a configuration in which the power semiconductor device 7 installed in the opening 2 is covered with a thermal-conductive electromagnetic-wave absorbing cover 5P and the thermal-conductive electromagnetic-wave absorbing cover 5P is brought into direct contact with the wall surface 200 on which the unit attachment apparatus 100 is installed. In the present embodiment, the power semiconductor device 7 has a large height and protrudes from the opening 2 on the rear surface portion 1C of the plate member 1. This configuration is effective when the lid 6 is difficult to attach because the power semiconductor device 7 has a large height. Other configurations are identical to those of the first embodiment, and thus explanations thereof will be omitted.

Also this configuration provides effective heat releasing property and electromagnetic-wave absorbing property. The assembly is also fairly satisfactory.

Furthermore, regardless of the height of the power semiconductor device 7 to be installed and even when the power semiconductor device 7 protrudes from the rear surface portion 1C of the plate member 1, the electromagnetic-wave absorbing cover 5P can be mounted to efficiently close the opening 2 due to the elasticity. Therefore, this structure is considerably high in the versatility.

The thermal-conductive electromagnetic-wave absorbing cover 5P has an identical composition to that of the thermal-conductive electromagnetic-wave absorbing sheet used in the first embodiment and is only different in being cut to a larger size to sufficiently close the opening 2. Furthermore, an area of the thermal-conductive electromagnetic-wave absorbing cover 5P corresponding to a peripheral edge portion of the opening 2 can be formed into a thin portion.

As described above, with the unit attachment apparatuses 100 according to the first to third embodiments, an extrudate is used as the plate member 1 constituting the housing of the unit attachment apparatus 100, so that the same mold can be used even when the number of the electronic device units 300 to be installed varies and it suffices to only adjust the length to which the extrudate is cut. Therefore, initial cost can be suppressed.

Furthermore, in the unit attachment apparatuses according to the first to third embodiments, the opening 2 is formed in the plate member 1 to be adapted to the positions of electronic components mounted on the motherboard 4 and the thermal-conductive electromagnetic-wave absorbing sheet 5 is provided between the plate member 1 and electronic components such as the power semiconductor device 7, so that electronic components having different sizes can be applied without changing the outer diameter of the plate member 1. Therefore, the manufacturing is easy and the assembly of the motherboard 4 to the plate member 1 by slide assembly is also easy. In this way, the unit attachment apparatuses, which are fairly thin, can remove heat of the electronic components mounted on the motherboard 4 and can block electromagnetic waves.

The protruding portions 61 provided on the lid 6 can prevent the motherboard 4 from being flawed at the time of assembly of the lid 6.

Installation of the motherboard 4 on the plate member 1 is performed by slide insertion. However, when an electronic component has a large height and causes slide insertion of the motherboard 4 to be difficult, the side surface portions 1S of the plate member 1 are shape-machined to have elasticity, so that the motherboard 4 can be inserted by expanding the side surface portions 1S.

Furthermore, by adjusting the thickness of the thermal-conductive electromagnetic-wave absorbing sheet, the versatility of the plate member 1 is enhanced and the cost can be lowered.

The first to third embodiments described above can be applied to an electronic device including a power supply unit and an arithmetic unit, and the like, without being limited to a programmable logic controller.

While the plate member 1 is formed by extrusion molding in the first to third embodiments described above, formation of the plate member 1 is not limited to shape machining by extrusion molding and can also be achieved by folding the plate member 1 by press molding.

Furthermore, while the plate member 1 is made of aluminum in the first to third embodiments described above, the material is not limited to aluminum and a stainless steel such as a special stainless steel called SUS301 can be applied. The special stainless steel is one of special steels that are obtained by adding a material such as chrome or nickel to iron to provide resistance to corrosion. A chrome-based or chrome-nickel-based addition element can be also applied as the addition element. The lid 6 can be made of other conductive materials having a satisfactory heat conductivity and a high resistance to noise, such as a stainless plate made of a specialty stainless steel called SUS301, similarly to the plate member 1, or aluminum, as well as an iron sheet.

The configurations according to the above embodiments are only examples of the contents of the present invention. The configurations can be combined with other well-known techniques, and can be configured while modifying or omitting a part the configuration without departing from the scope of the invention.

### REFERENCE SIGNS LIST

1 plate member, 1S side surface portion, 1C rear surface portion, 1A first principal surface, 1B second principal surface, 2 opening, 3 housing space, 4 motherboard, 4A first principal surface, 4B second principal surface, 5, 5S electromagnetic-wave absorbing sheet, 5P electromagnetic-wave absorbing cover, 6 lid, 7 power semiconductor device, 8a, 8b groove portion, 11 stepped portion, 20 connector, 61 protruding portion, 61a first protruding piece, 61b second protruding piece, 62 fixing piece, 63 screw, 100 unit attachment apparatus, 200 wall surface, 300 electronic device unit.

1. A unit attachment apparatus comprising:
a plate member that is a metallic extrusion-molded plate including engaging portions on two sides along a longitudinal direction;
an opening that is provided at a part of the plate member;
a lid that is attached to close the opening hole;
a motherboard that engages with the engaging portions of the plate member to be installed on the plate member, and that forms a housing space between the motherboard and the plate member, and that has an electronic component mounted on a side of the opening;
a thermal-conductive electromagnetic-wave absorbing sheet that is installed on a rear surface of the electronic component; wherein the electronic component is abutted on the lid via the thermal-conductive electromagnetic-wave absorbing sheet interposed therebetween.

2. (canceled)

3. The unit attachment apparatus according to claim 1, wherein the lid covers the opening and engages with the opening.

4. The unit attachment apparatus according to claim 3, wherein
the lid has a protruding portion that is U-shaped in cross section at an end portion of the lid,
the plate member has a stepped portion on a peripheral edge of the opening, and
the protruding portion and the stepped portion are fitted with each other.

5. The unit attachment apparatus according to claim 4, wherein the thermal-conductive electromagnetic-wave absorbing sheet is elastically fixed between the lid and the electronic component.

6. (canceled)

7. The unit attachment apparatus according to claim 1, wherein
the plate member has a rear surface portion, and side surface portions provided from two facing sides along the first direction of the rear surface portion toward the motherboard, and
the plate member has groove portions on the side surface portions, respectively, for installing two sides of the motherboard therein.

8. The unit attachment apparatus according to claim 1, wherein the motherboard has installation portions on the first principal surface, to which a plurality of electronic device units are to be respectively installed.

9. An electronic device system comprising:
the unit attachment apparatus according to claim 1, and
an electronic device unit installed on the first principal surface of the motherboard.

10. A manufacturing method of a unit attachment apparatus, the method comprising:
a step of forming a metallic plate member including engaging portions on two sides along a longitudinal direction and having an opening provided at a part thereof by extrusion molding;
a step of slidingly inserting a motherboard on which an electronic component is mounted into the engaging portions of the plate member to be engaged with the engaging portions, and forming a housing space between the motherboard and the plate member; and
a step of installing a thermal-conductive electromagnetic-wave absorbing sheet on a rear surface of the electronic component from a side of the opening, and abutting a lid on the electronic component via the thermal-conductive electromagnetic-wave absorbing sheet interposed therebetween to close the opening.
